(19) United States
(12) Patent Application Publication
(10) Pub. No.: US 2025/0324741 A1
(43) Pub. Date: Oct. 16, 2025

(54) SILICON CARBIDE SEMICONDUCTOR DEVICE AND METHOD OF MANUFACTURING THE SAME

(71) Applicant: FUJI ELECTRIC CO., LTD., Kawasaki-shi (JP)

(72) Inventor: Keiji OKUMURA, Matsumoto-city (JP)

(73) Assignee: FUJI ELECTRIC CO., LTD., Kawasaki-shi (JP)

(21) Appl. No.: 19/249,293

(22) Filed: Jun. 25, 2025

Related U.S. Application Data
(63) Continuation of application No. PCT/JP2024/020731, filed on Jun. 6, 2024.

(30) Foreign Application Priority Data
Jul. 24, 2023 (JP) 2023-119859

(51) Int. Cl. H10D 84/00; H01L 21/04; H10D 62/832; H10D 84/01

(52) U.S. Cl. CPC H10D 84/146; H01L 21/047; H10D 62/8325; H10D 84/0109

(57) ABSTRACT

Provided is a method of manufacturing a silicon carbide semiconductor device capable of ensuring an ohmic contact between a semiconductor layer including silicon carbide and an electrode without any silicide layer provided. The method of manufacturing the silicon carbide semiconductor device, includes: implanting impurity ions into a top surface of a first semiconductor layer including 4H-SiC in a direction inclined at an angle of 30 degrees or greater and less than 90 degrees to a normal line to the top surface of the first semiconductor layer so as to form a second semiconductor layer including 3C-SiC at least at a top surface on the top surface side of the first semiconductor layer; and forming a main electrode on the top surface side of the second semiconductor layer.

### CROSS-REFERENCE TO RELATED APPLICATION

This application is a Continuation of PCT Application No. PCT/JP2024/020731, filed on Jun. 6, 2024, and claims the priority of Japanese Patent Application No. 2023-119859, filed on Jul. 24, 2023, the content of which are incorporated herein by reference.

### TECHNICAL FIELD

The present disclosure relates to silicon carbide semiconductor devices including silicon carbide (SiC) and methods of manufacturing the same.

### BACKGROUND ART

JP2022-31923A discloses a method of forming a semiconductor structure including providing a silicon carbide layer having a crystallographic axis, heating the silicon carbide layer to a temperature of 300° C. or more, implanting dopant ions into the heated silicon carbide layer at an implant angle between a direction of implantation and the crystallographic axis of less than about 2°, and annealing the silicon carbide layer at a time-temperature product of less than 30,000° C.-hours so as to activate the implanted ions.

JP2022-144217A discloses a semiconductor device including a silicon carbide layer having a first face having an off-angle of zero degrees or greater and eight degrees or smaller with respect to a {0001} plane and a second face opposite to the first face, the silicon carbide layer having a 4H-SiC crystal structure, and the silicon carbide layer including a first silicon carbide region of p-type, a second silicon carbide region of n-type located between the first silicon carbide region and the first face, and a third silicon carbide region located between the first silicon carbide region and the first face and containing oxygen, the second silicon carbide region being located between the third silicon carbide region and the first face, a gate electrode, a silicon oxide layer located between the silicon carbide layer and the gate electrode, and a region located between the silicon carbide layer and the silicon oxide layer and having a nitrogen concentration of 1×10²¹ cm⁻³ or more.

JP7015750B2 discloses an electronic device including a silicon carbide drift region having a first conductivity-type and a first doping concentration, a well region in the drift region, the well region having a second conductivity-type opposite the first conductivity-type and having a second doping concentration, and a deeply-implanted region provided below the well region, the deeply-implanted region having the second conductivity-type and a third doping concentration that is greater than the first doping concentration and less than the second doping concentration, wherein the drift region includes a drift layer having the first doping concentration and a current spreading layer having a fourth doping concentration on the drift layer, the fourth doping concentration is higher than the first doping concentration of the drift layer and lower than the third doping concentration of the deeply-implanted region, and the deeply-implanted region extends to a depth that is less than a thickness of the current spreading layer.

JP6391689B2 discloses a method of forming a semiconductor structure including providing a silicon carbide layer having a crystallographic axis, heating the silicon carbide layer to a temperature of 300° C. or more, implanting dopant ions into the heated silicon carbide layer at an implant angle between a direction of implantation and the crystallographic axis of less than about 2°, and annealing the silicon carbide layer at a time-temperature product of less than 30,000° C.-hours so as to activate the implanted ions, wherein the implanting the dopant ions includes implanting the dopant ions at an implant energy of about 100 keV or less with a dose of less than 1E13 cm⁻².

JP6584253B2 and WO2017/047350A1 each disclose a SiC epitaxial wafer including a substrate having a low-off angle of less than 4 degrees, and a SiC epitaxial growth layer provided on the substrate, wherein the SiC epitaxial growth layer uses a Si compound as a supply source of Si and uses a C compound as a supply source of C, the SiC epitaxial growth layer has a uniformity of carrier density of less than 10% and a defect density of less than 1 count/cm², and a C/Si ratio between the Si compound and the C compound is within a range of 0.7 or greater and 0.95 or less.

JP6479347B2 and WO2015/186791A1 each disclose a method of manufacturing a SiC epitaxial wafer including preparing a SiC ingot, cutting the prepared SiC ingot with an off angle, and polishing the cut SiC ingot to form a SiC bare wafer having a (0001) plane, removing a cut surface of the SiC bare wafer to form a SiC substrate, and crystal-growing a SiC epitaxial growth layer on the SiC substrate, wherein a material gas to be supplied at the time of the epitaxial growth includes a Si compound used as a supply source of Si and a C compound used as a supply source of C, both of the Si compound gas and the C compound gas or the Si compound includes a compound containing fluorine, and a surface-roughness defect density including particles on a surface of the SiC epitaxial growth layer is controlled to be less than 0.07 count/cm².

JP6169966B2 discloses a semiconductor device including an element region provided with an insulated-gate switching element, and a circumferential region adjacent to the element region, wherein a first trench and a second trench are provided in the circumferential region, a front surface region of a second conductivity-type is provided between the first trench and the second trench, a first bottom surface region of the second conductivity-type is provided on a bottom surface of the first trench, a second bottom surface region of the second conductivity-type is provided on a bottom surface of the second trench, a first side surface region of the second conductivity-type connecting the front surface region and the first bottom surface region is provided along a side surface of the first trench, a second side surface region of the second conductivity-type connecting the front surface region and the second bottom surface region is provided along a side surface of the second trench, and a low area density region is provided in at least a part of the first side surface region and the second side surface region.

### SUMMARY OF THE INVENTION

### Technical Problem

Providing silicon carbide semiconductor devices with a silicide layer including nickel silicide (NiSi) or the like has been examined in order to ensure an ohmic contact between a semiconductor layer including silicon carbide and an electrode.

However, the provision of such a silicide layer tends to cause roughness on the surface, which leads to a bad influence on reliability of products.

In view of the foregoing problems, the present disclosure provides a silicon carbide semiconductor device and a method of manufacturing the same capable of ensuring an ohmic contact between a semiconductor layer including silicon carbide and an electrode without any silicide layer provided.

### Solution to Problem

To solve the problems described above, an aspect of the present disclosure inheres in a silicon carbide semiconductor device including: a first semiconductor layer including 4H-SiC; a second semiconductor layer provided on a top surface side of the first semiconductor layer and including 3C-SiC at least at a top surface; and a main electrode provided on the top surface side of the second semiconductor layer, wherein an impurity concentration from the top surface of the second semiconductor layer to a depth of 0.3 micrometers is 1×10¹⁸/cm³ or higher, an impurity concentration at a depth of 0.5 micrometers or greater away from the top surface of the second semiconductor layer is 1×10¹⁷/cm³ or lower.

Another aspect of the present disclosure inheres in a method of manufacturing a silicon carbide semiconductor device, including: implanting impurity ions into a top surface of a first semiconductor layer including 4H-SiC in a direction inclined at an angle of 30 degrees or greater and less than 90 degrees to a normal line to the top surface of the first semiconductor layer so as to form a second semiconductor layer including 3C-SiC at least at a top surface on the top surface side of the first semiconductor layer; and forming a main electrode on the top surface side of the second semiconductor layer.

### BRIEF DESCRIPTION OF THE DRAWINGS

FIG. 1 is a plan view illustrating a silicon carbide semiconductor device according to a first embodiment;

FIG. 2 is a cross-sectional view as viewed from direction A-A in FIG. 1;

FIG. 3 is a cross-sectional view as viewed from direction B-B in FIG. 1;

FIG. 4 is a cross-sectional process view illustrating a method of manufacturing the silicon carbide semiconductor device according to the first embodiment;

FIG. 5 is a cross-sectional process view continued from FIG. 4, illustrating the method of manufacturing the silicon carbide semiconductor device according to the first embodiment corresponding to FIG. 2;

FIG. 6 is a cross-sectional process view continued from FIG. 4, illustrating the method of manufacturing the silicon carbide semiconductor device according to the first embodiment corresponding to FIG. 3;

FIG. 7 is a cross-sectional view illustrating a case of implanting impurity ions obliquely at an off-angle of a semiconductor substrate;

FIG. 8 is another cross-sectional view illustrating a case of implanting impurity ions obliquely at an angle opposite to the off-angle of the semiconductor substrate;

FIG. 9 is a cross-sectional view illustrating a silicon carbide semiconductor device of a first comparative example;

FIG. 10 is a cross-sectional view illustrating a silicon carbide semiconductor device of a second comparative example;

FIG. 11 is a graph showing simulation results of profiles of impurities by ion implantation in a vertical direction when varying acceleration energy;

FIG. 12 is a graph showing simulation results of profiles of impurities by ion implantation in an oblique direction when varying acceleration energy;

FIG. 13 is a graph showing simulation results of profiles of impurities by ion implantation when varying an implantation angle;

FIG. 14 is a cross-sectional view illustrating a silicon carbide semiconductor device according to a second embodiment;

FIG. 15 is a cross-sectional process view illustrating a method of manufacturing the silicon carbide semiconductor device according to the second embodiment;

FIG. 16 is a cross-sectional view illustrating a silicon carbide semiconductor device according to a third embodiment;

FIG. 17 is a cross-sectional process view illustrating a method of manufacturing the silicon carbide semiconductor device according to the third embodiment;

FIG. 18 is a cross-sectional view illustrating a silicon carbide semiconductor device according to a fourth embodiment;

FIG. 19 is a cross-sectional process view illustrating a method of manufacturing the silicon carbide semiconductor device according to the fourth embodiment;

FIG. 20 is a cross-sectional process view continued from FIG. 19, illustrating the method of manufacturing the silicon carbide semiconductor device according to the fourth embodiment;

FIG. 21 is a cross-sectional process view continued from FIG. 20, illustrating the method of manufacturing the silicon carbide semiconductor device according to the fourth embodiment;

FIG. 22 is a cross-sectional process view continued from FIG. 21, illustrating the method of manufacturing the silicon carbide semiconductor device according to the fourth embodiment;

FIG. 23 is a cross-sectional process view continued from FIG. 22, illustrating the method of manufacturing the silicon carbide semiconductor device according to the fourth embodiment;

FIG. 24 is a cross-sectional process view continued from FIG. 23, illustrating the method of manufacturing the silicon carbide semiconductor device according to the fourth embodiment;

FIG. 25 is a cross-sectional process view continued from FIG. 24, illustrating the method of manufacturing the silicon carbide semiconductor device according to the fourth embodiment;

FIG. 26 is a cross-sectional process view continued from FIG. 25, illustrating the method of manufacturing the silicon carbide semiconductor device according to the fourth embodiment;

FIG. 27 is a cross-sectional process view continued from FIG. 26, illustrating the method of manufacturing the silicon carbide semiconductor device according to the fourth embodiment;

FIG. 28 is a cross-sectional process view continued from FIG. 27, illustrating the method of manufacturing the silicon carbide semiconductor device according to the fourth embodiment;

FIG. 29 is a cross-sectional process view continued from FIG. 28, illustrating the method of manufacturing the silicon carbide semiconductor device according to the fourth embodiment;

FIG. 30 is a cross-sectional process view continued from FIG. 29, illustrating the method of manufacturing the silicon carbide semiconductor device according to the fourth embodiment;

FIG. 31 is a cross-sectional process view continued from FIG. 30, illustrating the method of manufacturing the silicon carbide semiconductor device according to the fourth embodiment;

FIG. 32 is a cross-sectional view illustrating a silicon carbide semiconductor device according to a fifth embodiment; and

FIG. 33 is a cross-sectional view illustrating a silicon carbide semiconductor device according to a sixth embodiment.

### DETAILED DESCRIPTION

With reference to the drawings, first to sixth embodiments of the present disclosure will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to sixth embodiments described below merely illustrate schematically devices and methods for specifying and giving shapes to the technical idea of the present disclosure, and the span of the technical idea is not limited to materials, shapes, structures, and relative positions of elements described herein.

In the present disclosure, a source region of a metal-oxide-semiconductor field-effect transistor (MOSFET) is referred to as “one of the main regions (a first main region)” that can be used as an emitter region in an insulated gate bipolar transistor (IGBT) or as a cathode region in a thyristor such as a MOS controlled static induction thyristor (SI thyristor) or a diode. A drain region of the MOSFET is referred to as the “other one of the main regions (a second main region)” of the semiconductor device that can be used as a collector region in the IGBT or as an anode region in the thyristor or the diode. The term “main region”, when simply mentioned in the present disclosure, is referred to as either “one of the main regions (the first main region)” or “other one of the main regions (the second main region)” that is determined as appropriate by the person skilled in the art.

Further, definitions of directions such as an up-and-down direction in the present disclosure are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the present disclosure, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

In addition, in the Miller index notation of the present disclosure, “−” denotes a bar attached to the index following the Miller index, and a negative sign is represented by attaching “−” before the index.

Further, SiC crystals have polymorphism, and main examples include a cubic 3C structure (3C-SiC), and hexagonal 4H structure (4H-SiC) and 6H structure (6H-SiC). It has been reported that a bandgap at room temperature is 2.23 eV for 3C-SiC, 3.26 eV for 4H-SiC, and 3.02 eV for 6H-SiC. The present disclosure illustrates a case of mainly using 4H-SiC and 3C-SiC.

### First Embodiment

### Configuration of Silicon Carbide Semiconductor Device

A silicon carbide semiconductor device according to a first embodiment is illustrated below with a diode having a merged PN Schottky (MPS) structure. The MPS structure includes a Schottky junction and a p-n junction provided together on the top surface side of a semiconductor substrate.

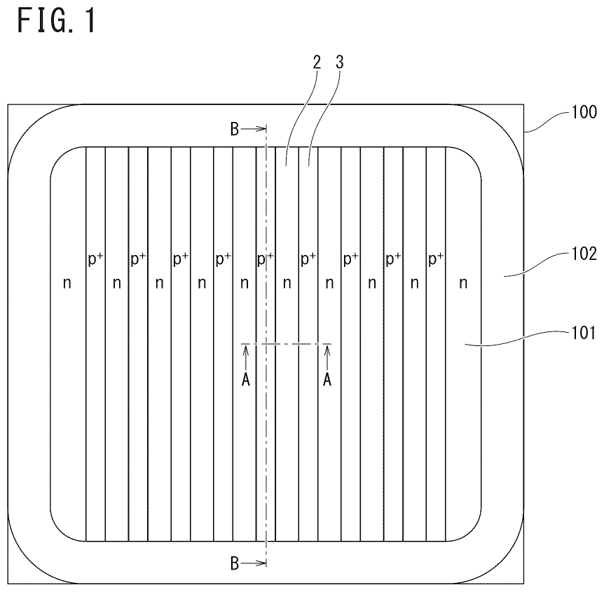

FIG. 1 is a plan view illustrating the silicon carbide semiconductor device according to the first embodiment. The silicon carbide semiconductor device according to the first embodiment includes an active area 101 provided in a semiconductor substrate (a semiconductor base body) 100, and an edge termination area 102 provided in the semiconductor substrate 100 to surround the circumference of the active area 101. The active area 101 is an area through which a current flows when the diode is in an ON-state. The edge termination area 102 is an area provided for relaxing an electric field applied to an end part of the active area 101 to ensure a breakdown voltage.

The active area 101 is provided with a plurality of anode regions 3, which are semiconductor layers of a second conductivity-type (p⁺-type), on the top surface side of a drift layer 2, which is a semiconductor layer of a first conductivity-type (n-type). The anode regions 3 have straight (stripe-shaped) parts extending parallel to each other in one direction (in the upper-lower direction in FIG. 1) in the planar pattern. The anode regions 3 are arranged separately from each other in the direction orthogonal to the extending direction (in the right-left direction in FIG. 1). The number of the anode regions 3 to be arranged next to each other can be changed as appropriate.

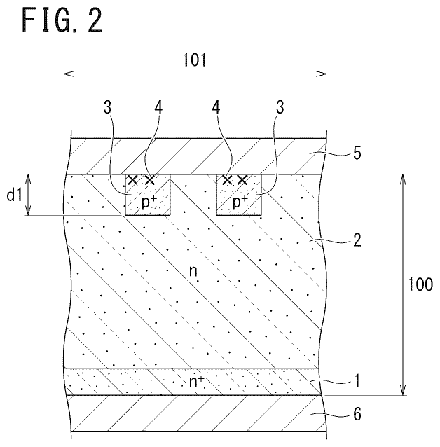

FIG. 2 is a cross-sectional view, as viewed from direction A-A in FIG. 1, taken along a direction orthogonal to the extending direction of the anode regions 3. As illustrated in FIG. 2, a cathode region 1 of the first conductivity-type (n⁺-type) is provided on the bottom surface side of the semiconductor substrate 100. The cathode region 1 is a substrate (a SiC substrate) including SiC such as 4H-SiC.

The first conductivity-type (n-type) drift layer 2 having a lower impurity concentration than the cathode region 1 is provided on the top surface side of the cathode region 1. The drift layer 2 is an epitaxial growth layer including SiC such as 4H-SiC. A buffer layer of n-type may be interposed between the cathode region 1 and the drift layer 2. The n-type buffer layer may have a lower impurity concentration than the cathode region 1 and a higher impurity concentration than the drift layer 2.

The plural p⁺-type anode regions 3 are provided separately from each other on the top surface side of the drift layer 2. The respective p⁺-type anode regions 3 and the n-type drift layer 2 implement a p-n junction. The respective anode regions 3 are formed such that p-type impurity ions such as aluminum (Al) and boron (B) are implanted into the drift layer 2. The anode regions 3 each have a substantially rectangular shape in cross section as viewed from direction A-A in FIG. 1, taken along the direction orthogonal to the extending direction of the anode regions 3 in the planar pattern.

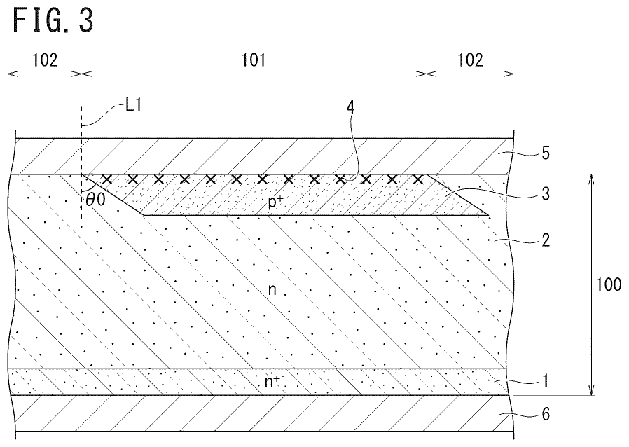

FIG. 3 is a cross-sectional view, as viewed from direction B-B in FIG. 1, taken along the extending direction of the respective anode regions 3. The anode regions 3 each have a substantially parallelogram in cross section along the extending direction of the anode regions 3 in the planar pattern. The top surface and the bottom surface of each anode region 3 are substantially parallel to each other, and the inclined side surfaces on both sides of each anode region 3 are substantially parallel to each other. An angle θ0 between the normal line L1 to the top surface of the semiconductor substrate 100 and the inclined side surface of the anode region 3 is in a range of about 30 degrees or greater and less than 90 degrees, for example. The respective anode regions 3 are formed such that the p-type impurity ions are implanted into the semiconductor substrate 100 in an oblique direction inclined to the normal line L1 to the top surface of the semiconductor substrate 100 so as to have a substantially parallelogram in cross section. The side surfaces of the respective anode regions 3 are substantially parallel to the direction in which the impurity ions are implanted.

Although not illustrated in FIG. 3, an electric-field relaxation layer of p-type is provided on the top surface side of the drift layer 2 in the edge termination area 102. The respective anode regions 3 do not necessarily have the substantially parallelogram in cross section when the electric-field relaxation layer is in contact with or overlaps with the end part of the respective anode regions 3.

A depth dl of the respective anode regions 3 is set in a range of about 0.1 micrometers or greater and 0.5 micrometers or less, or may be set in a range of 0.1 micrometers or greater and 0.3 micrometers or less for example. The depth d1 of the respective anode regions 3 may be about 0.5 micrometers or greater. The depth d1 of the respective anode regions 3 is set to be shallower as the inclined angle of the ion implantation for forming the anode regions 3 with respect to the normal line L1 to the top surface of the semiconductor substrate 100 is larger.

An impurity concentration in a region from the top surface of the respective anode regions 3 to the depth of 0.3 micrometers is set in a range of about 1×10¹⁸/cm³ or higher and 1×10²²/cm³ or lower, and is preferably set in a range of about 1×10¹⁹/cm³ or higher and 1×10²²/cm³ or lower so as to have lower resistance. An impurity concentration at the top surface of the respective anode regions 3 may be in a range of about 1×10²⁰/cm³ or higher and 1×10²²/cm³ or lower. The impurity concentration in the region from the top surface of the respective anode regions 3 to the depth of about 0.3 micrometers in the depth direction perpendicular to the top surface of the respective anode regions 3 may be uniform, and the impurity concentration in the region from the top surface of the respective anode regions 3 to the depth of about 0.4 micrometers may be uniform. The expression “the impurity concentration is uniform” encompasses not only a case of being strictly uniform but also a case of fluctuating within a range of ±10%.

An impurity concentration in a depth of 0.5 micrometers or deeper away from the top surface of the respective anode regions 3 in the depth direction perpendicular to the top surface of the respective anode regions 3 is lower than the impurity concentration in the region from the top surface of the respective anode regions 3 to the depth of 0.3 micrometers. The impurity concentration in the depth of 0.5 micrometers or deeper away from the top surface of the respective anode regions 3 is about 1×10¹⁷/cm³ or lower, for example.

As schematically indicated by the symbol “x” in FIG. 2 and FIG. 3, damage 4 is caused to a part on the top surface side (also referred to below as an “upper part” or a “front-surface layer”) including at least the top surface of the respective anode regions 3 during the ion implantation for forming the anode regions 3, so as to destroy the crystal structure of 4H-SiC to provide an amorphous structure. The following annealing (activation annealing) executed later forms 3C-SiC when the amorphous structure is recrystallized. The front-surface layer of the respective anode regions 3 thus includes 3C-SiC.

A proportion of 3C-SiC included in the front-surface layer of the respective anode regions 3 is in a range of about 10% or higher and 100% or lower, for example. The front-surface layer of the respective anode regions 3 may include mixed crystals of 3C-SiC and 4H-SiC. The front-surface layer of the respective anode regions 3 may further have an amorphous structure, 4H-SiC, and the like, in addition to 3C-SiC. The inclusion of 3C-SiC, which has a narrower bandgap than 4H-SiC, in the front-surface layer of the respective anode regions 3 can lead to an ohmic contact with an anode electrode 5 on the top surface side of the anode regions 3 at low resistance. A part on the lower side (the lower part) of the front-surface layer of the respective anode regions 3 may include 4H-SiC.

The crystal structure such as 3C-SiC and 4H-SiC may be measured (observed) by field-emission scanning electron microscopy (FE-SEM) and electron backscatter diffraction (EBSD), for example, so as to measure an area ratio of the crystal structure on the front surface.

As illustrated in FIG. 2 and FIG. 3, the anode electrode (top-surface electrode) 5 is provided on the top surface sides of the drift layer 2 and the anode regions 3. FIG. 1 omits the illustration of the anode electrode 5. The anode electrode 5 is in contact with the respective top surfaces of the drift layer 2 and the anode regions 3. The anode electrode 5 includes metal such as aluminum (Al), an Al alloy, and molybdenum (Mo). Examples of Al alloys include Al-silicon (Si), Al-copper (Cu), and Al—Si—Cu.

The anode electrode 5 can be provided with a barrier metal layer in a part in contact with the anode regions 3. The barrier metal layer may include metal such as titanium nitride (TiN), titanium (Ti), and TiN/Ti with a stacked structure including Ti as a lower layer. The part of the anode electrode 5 in contact with the anode regions 3 includes metal material such as aluminum (Al), an Al alloy, molybdenum (Mo), titanium (Ti), and titanium nitride (TiN).

Since the front-surface layer of the respective anode regions 3 includes 3C-SiC, the anode regions 3 are in ohmic contact with the anode electrode 5 at low resistance. Any silicide layers including nickel silicide (NiSi) or the like are thus not provided between the anode electrode 5 and the respective anode regions 3. The drift layer 2 interposed between the anode regions 3 adjacent to each other implements a Schottky junction with the anode electrode 5.

The silicon carbide semiconductor device according to the first embodiment has the MPS structure in which the p-n junction implemented by the plural anode regions 3 and the drift layer 2 and the Schottky junction implemented by the drift layer 2 interposed between the respective anode regions 3 and the anode electrode 5 are provided together. This structure can decrease an electric-field intensity at the junction surface between the semiconductor substrate 100 and the anode electrode 5, so as to suppress a reverse leakage current.

As illustrated in FIG. 2 and FIG. 3, a cathode electrode (a rear-surface electrode) 6 is provided on the bottom surface side of the cathode region 1. The cathode electrode 6 is either a single film including metal such as gold (Au) or a stacked film including titanium (Ti), nickel (Ni), and gold (Au) sequentially stacked together. A silicide layer may be further interposed between the cathode region 1 and the cathode electrode 6.

### Method of Manufacturing Silicon Carbide Semiconductor Device

An example of a method of manufacturing the silicon carbide semiconductor device according to the first embodiment is described below mainly with reference to the cross section corresponding to FIG. 2.

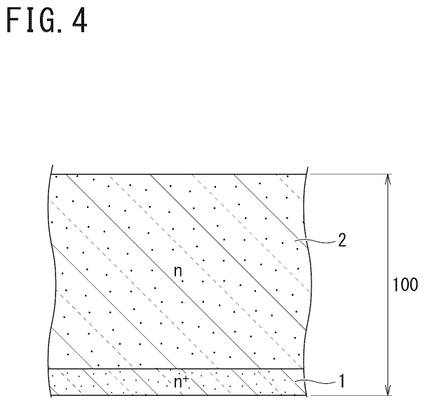

First, the cathode region 1 is prepared as a starting substrate that is a SiC substrate of the first conductivity-type (n⁺-type) including SiC such as 4H-SiC and doped with n-type impurities such as nitrogen (N) (refer to FIG. 4). The top surface of the cathode region 1 may have an off-angle of about zero degrees to eight degrees (for example, about four degrees). Next, as illustrated in FIG. 4, the drift layer 2 of the first conductivity-type (n-type) including SiC such as 4H-SiC and doped with n-type impurities such as N is epitaxially grown on the cathode region 1. When the top surface of the cathode region 1 has the off-angle, the top surface of the drift layer 2 also has a similar off-angle. The cathode region 1 and the drift layer 2 implement the semiconductor substrate 100.

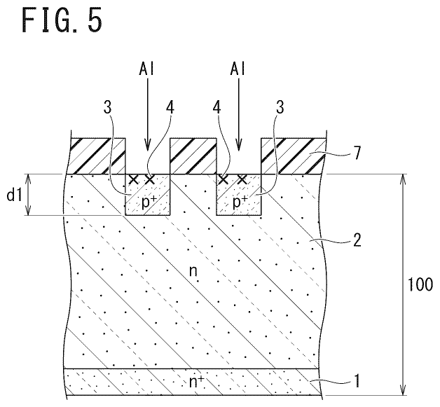

Next, a photoresist film 7 is applied to the top surface of the drift layer 2 (refer to FIG. 5), and is delineated by photolithography. Using the delineated photoresist film 7 as a mask for ion implantation, p-type impurity ions such as aluminum (Al) are implanted to the top surface of the drift layer 2, so as to form the p⁺-type anode regions 3 on the top surface side of the drift layer 2, as illustrated in FIG. 5.

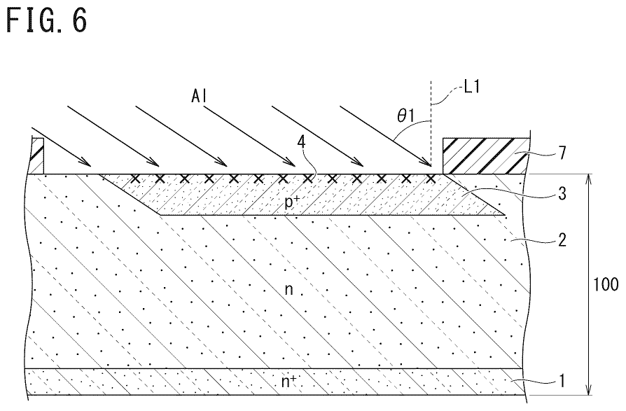

FIG. 6 is a cross-sectional view, corresponding to FIG. 3, upon the ion implantation illustrated in FIG. 5. As illustrated in FIG. 6, the p-type impurity ions are implanted obliquely into the semiconductor substrate 100 at a predetermined angle θ1 inclined with respect to the normal line L1 to the top surface of the semiconductor substrate 100. The predetermined angle θ1 is set in a range of about 30 degrees or greater and less than 90 degrees, or may be in a range of about 45 degrees or greater and less than 90 degrees or in a range of about 60 degrees or greater and less than 90 degrees, for example. The anode regions 3 are formed in a shallower part as the predetermined angle θ1 is greater. As illustrated in FIG. 6, causing the direction of the ion implantation to be inclined in the longitudinal direction (the extending direction) of the anode regions 3 in the planar pattern can avoid shadowing, which is a shift of the mask from the ion implantation.

An acceleration energy during the ion implantation is set in a range of about 300 keV or higher and 700 keV or lower, or may be in a range of about 400 keV or higher and 700 keV or lower. Setting the acceleration energy during the ion implantation to as high as 300 keV or higher can cause the damage 4 to the front-surface layer of the respective anode regions 3, as schematically indicated by the symbol “x” in FIG. 5 and FIG. 6, so as to destroy the crystal structure of 4H-SiC to obtain the amorphous structure. The damage 4 tends to be caused more easily as the acceleration energy during the ion implantation is higher.

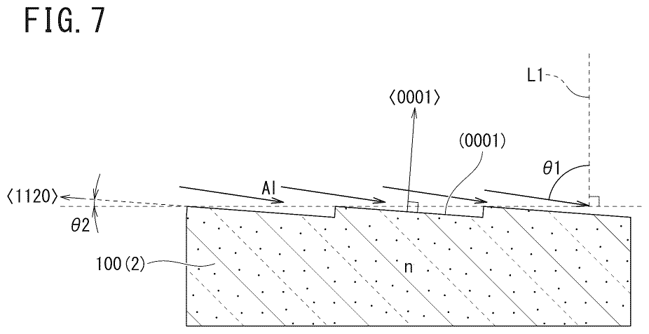

A presumed case is described below in which the semiconductor substrate 100 has an off-angle θ2 in a <11-20> direction with respect to a <0001> (c-axis) direction, as illustrated in FIG. 7. The off-angle θ2 is defined between a surface (a ground surface) perpendicular to the c-axis, which is a (0001) plane (a silicon (Si) plane) or a (000-1) plane (a carbon (C) plane), and the top surface of the semiconductor substrate 100 indicated by the broken line.

As illustrated in FIG. 7, when the direction of the ion implantation is inclined at the predetermined angle θ1 in the direction with the off-angle θ2 (the off-angle direction) with respect to the normal line L1 to the top surface of the semiconductor substrate 100, the predetermined angle θ1 is set to about less than (90°-θ2) which is less than the angle parallel to the off-angle direction. This configuration can prevent the implantation direction from being parallel to the off-angle θ2, so as to equalize the ion implantation. When the off-angle θ2 of the semiconductor substrate 100 is four degrees, for example, the implantation angle θ1 may be less than 86 degrees.

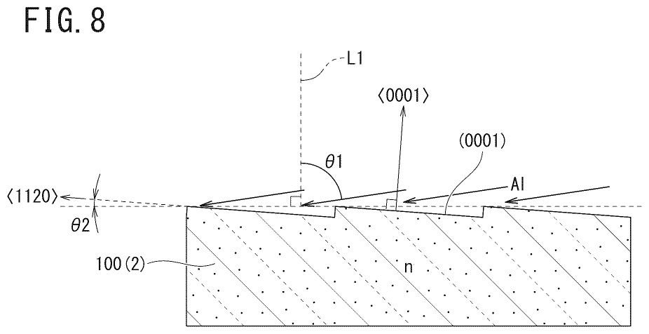

When the direction of the ion implantation is inclined in a direction different from the off-angle θ2, as illustrated in FIG. 8, the predetermined angle θ1 with respect to the normal line L1 to the top surface of the semiconductor substrate 100 is set to less than about 90 degrees, so as to equalize the ion implantation. FIG. 8 illustrates the case in which the ion implantation is inclined in the direction opposite to the off-angle direction. In this case, the implantation angle θ1 can be set to about less than 90 degrees.

Next, annealing (activation annealing) at a temperature in a range of about 1600° C. or higher and 1900° C. or lower is executed so as to activate the implanted p-type impurity ions. The execution of the annealing recrystallizes the amorphous structure in the front-surface layer of the respective anode regions 3 to provide 3C-SiC.

Next, the anode electrode 5 including aluminum (Al) or the like is formed on the top surface sides of the drift layer 2 and the anode regions 3 by sputtering or evaporation method (refer to FIG. 2 and FIG. 3). The drift layer 2 and the anode electrode 5 implement the Schottky junction, while the anode regions 3 and the anode electrode 5 are in ohmic contact with each other at low resistance.

Next, the semiconductor substrate 100 is ground from the bottom surface side so that the thickness of the semiconductor substrate 100 is adjusted to an intended thickness of a product. Next, the cathode electrode 6 including gold (Au) or the like is formed on the entire bottom surface of the semiconductor substrate 100 by sputtering or evaporation method (refer to FIG. 2 and FIG. 3). Thereafter, the semiconductor substrate 100 is cut (diced) into individual pieces, so as to complete the silicon carbide semiconductor device according to the first embodiment.

### First Comparative Example

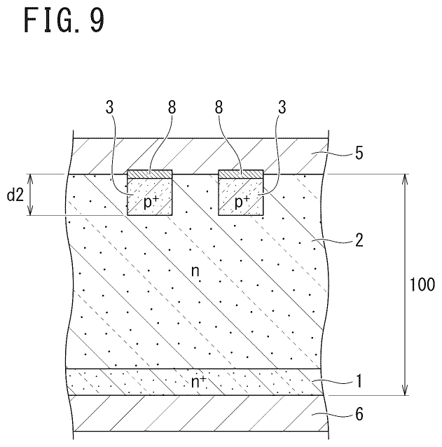

A silicon carbide semiconductor device of a first comparative example is described below. The silicon carbide semiconductor device of the first comparative example differs from the silicon carbide semiconductor device according to the first embodiment illustrated in FIG. 2 in including silicide layers 8 including nickel silicide (NiSi) between the p⁺-type anode regions 3 and the anode electrode 5, as illustrated in FIG. 9. A depth d2 of the anode regions 3 is equivalent to the depth d1 of the anode regions 3 in the silicon carbide semiconductor device according to the first embodiment illustrated in FIG. 2. The anode regions 3 include 4H-SiC, and the silicide layers 8 are interposed between the anode regions 3 and the anode electrode 5 so as to lead the anode regions 3 and the anode electrode 5 to be in ohmic contact with each other.

A method of manufacturing the silicon carbide semiconductor device of the first comparative example executes the implantation of the p-type impurity ions for forming the anode regions 3 in the normal line direction to the top surface of the semiconductor substrate 100 with no inclination to the normal line. The acceleration energy during the ion implantation is less than 300 keV, which is lower than the acceleration energy during the ion implantation in the method of manufacturing the silicon carbide semiconductor device according to the first embodiment. No damage is thus caused to the front-surface layer of the respective anode regions 3, while the anode regions 3 keep 4H-SiC. The manufacturing method then forms a metal film including nickel (Ni) or the like on the top surface side of the anode regions 3, and executes annealing so as to form the silicide layers 8.

The silicon carbide semiconductor device of the first comparative example and the method of manufacturing the same tend to cause roughness on the surfaces of the silicide layers 8, which may have a bad influence on reliability of products because of deterioration in coverage of the barrier metal layer formed on the top surface side of the silicide layers 8. Further, the extra step of forming the silicide layers 8 is required so as to lead the anode regions 3 and the anode electrode 5 to be in ohmic contact with each other, which increases the total number of the steps and the costs accordingly.

In contrast, the silicon carbide semiconductor device according to the first embodiment and the method of manufacturing the same implant the p-type impurity ions for forming the anode regions 3 into the top surface of the drift layer 2 in the oblique direction inclined only at the predetermined angle θ1 with respect to the normal line L1 to the top surface of the semiconductor substrate 100. The present embodiment thus can form the anode regions 3 in the shallow part regardless of the high acceleration energy, and cause the damage 4 to the front-surface layer of the respective anode regions 3 to provide 3C-SiC, so as to lead the anode regions 3 and the anode electrode 5 to be in ohmic contact with each other at low resistance. The present embodiment thus does not need to provide any silicide layers between the anode regions 3 and the anode electrode 5, so as to avoid the problem with surface roughness caused on the silicide layers and improve the reliability of products, and further eliminate the step of forming the silicide layers and reduce the costs accordingly.

### Second Comparative Example

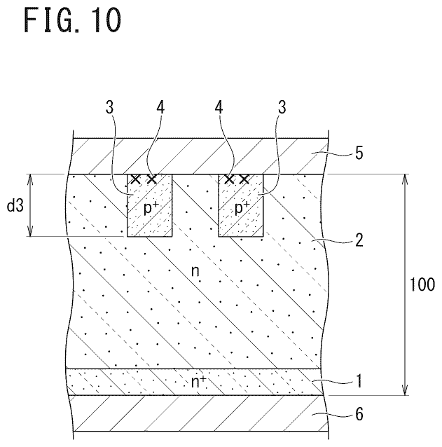

A silicon carbide semiconductor device of a second comparative example is described below. The silicon carbide semiconductor device of the second comparative example differs from the silicon carbide semiconductor device according to the first embodiment, as illustrated in FIG. 10, in that a depth d3 of the p⁺-type anode regions 3 is greater than the depth d1 of the anode regions 3 illustrated in FIG. 2. The damage 4 derived from the ion implantation for forming the anode region 3 is caused to the front-surface layer of the respective anode regions 3 including 3C-SiC. This comparative example thus leads the anode regions 3 and the anode electrode 5 to be in ohmic contact with each other at low resistance, while no silicide layers are provided between the anode regions 3 and the anode electrode 5.

A method of manufacturing the silicon carbide semiconductor device of the second comparative example executes the implantation of the p-type impurity ions for forming the anode regions 3 in the normal line direction to the top surface of the semiconductor substrate 100 with no inclination with respect to the normal line. The acceleration energy during the ion implantation is 300 keV or higher that is equivalent to the acceleration energy during the ion implantation in the method of manufacturing the silicon carbide semiconductor device according to the first embodiment, and the damage 4 is thus caused to the front-surface layer of the respective anode regions 3, so as to form 3C-SiC in the front-surface layer of the respective anode regions 3 after the annealing.

However, since the silicon carbide semiconductor device of the second comparative example, which executes the ion implantation at the high acceleration in the normal line direction to the top surface of the semiconductor substrate 100, the p-type impurities are implanted into a deep part, and the impurity concentration in the front-surface layer of the respective anode regions 3 is thus led to be low. For example, the silicon carbide semiconductor device of the second comparative example could have a part having an impurity concentration of less than 1×10¹⁸/cm³ within the area from the top surface of the respective anode regions 3 to the depth of 0.3 micrometers. The manufacturing method of this comparative example thus needs to execute multiple-step ion implantation with respect to the front-surface layer of the respective anode regions 3 in order to increase the impurity concentration, which inevitably increases a process load and also increases an implantation time for a high dose.

In contrast, the silicon carbide semiconductor device according to the first embodiment and the method of manufacturing the same implant the p-type impurity ions for forming the anode regions 3 into the top surface of the drift layer 2 in the oblique direction inclined only at the predetermined angle θ1 with respect to the normal line L1 to the top surface of the semiconductor substrate 100. The present embodiment thus can increase the impurity concentration in the front-surface layer of the respective anode regions 3 while causing the damage 4 to the top surface side of the anode regions 3, so as to reduce the process load reliably.

### Simulation Results

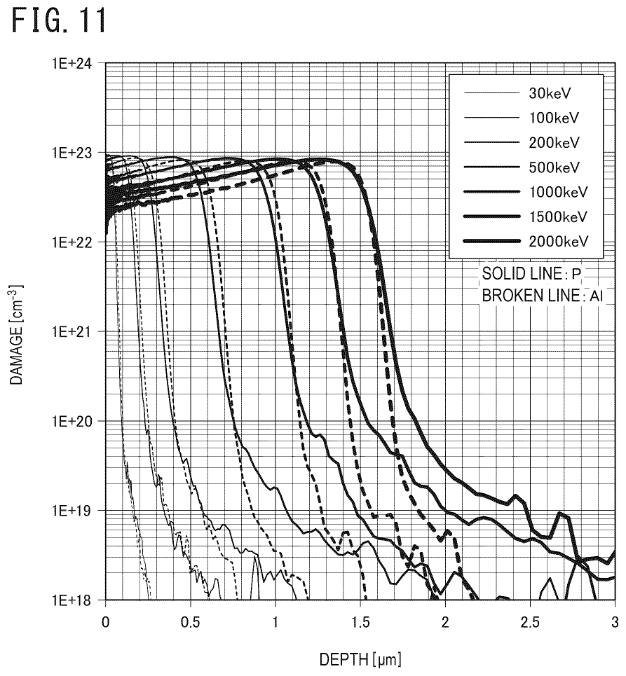

FIG. 11 is a graph showing results of Monte Carlo simulations of impurity profiles when impurity ions of phosphorus (P) or aluminum (Al) are implanted in the normal line direction to the top surface of the wafer with the acceleration energy during the ion implantation changed to 30 keV, 100 keV, 200 keV, 500 keV, 1000 keV, 1500 keV, and 2000 keV. The axis of abscissas in FIG. 11 indicates a depth from the top surface of the wafer, and the axis of ordinates in FIG. 11 indicates an impurity concentration (damage). The simulation revealed, as shown in FIG. 11, that the damage tends to be caused to a deeper position as the acceleration energy is higher.

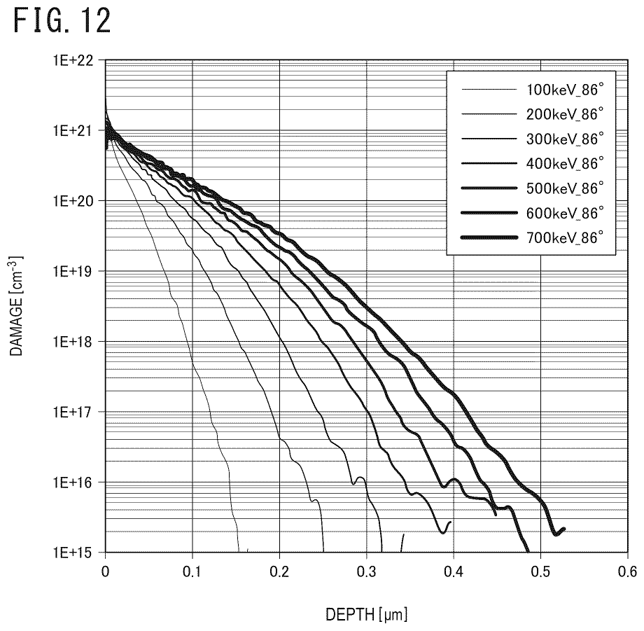

FIG. 12 is a graph showing results of Monte Carlo simulations of impurity profiles in a case of using Al as an ion species, setting an off-angle of the wafer to four degrees, setting a dose to 1×10¹³/cm², fixing an implantation angle with respect to the normal line direction to the top surface of the wafer to 86 degrees, and changing implantation energy to 100 keV, 200 keV, 300 keV, 400 keV, 500 keV, 600 keV, and 700 keV. The axis of abscissas in FIG. 12 indicates a depth from the top surface of the wafer, and the axis of ordinates in FIG. 12 indicates an impurity concentration (damage).

As shown in FIG. 12, a high-concentration damage layer having an impurity concentration of 1×10²⁰/cm⁻³ or higher needs to have a depth of 0.1 micrometers or greater from the top surface of the wafer. The reason for this is that the part with the depth of about 0.1 micrometers from the top surface of the wafer could disappear because of an oxidation process executed later. The acceleration energy is thus preferably set to 400 keV or higher so as to have the impurity concentration of about 1×10²⁰/cm⁻³ in the depth of about 0.1 micrometers from the top surface of the wafer.

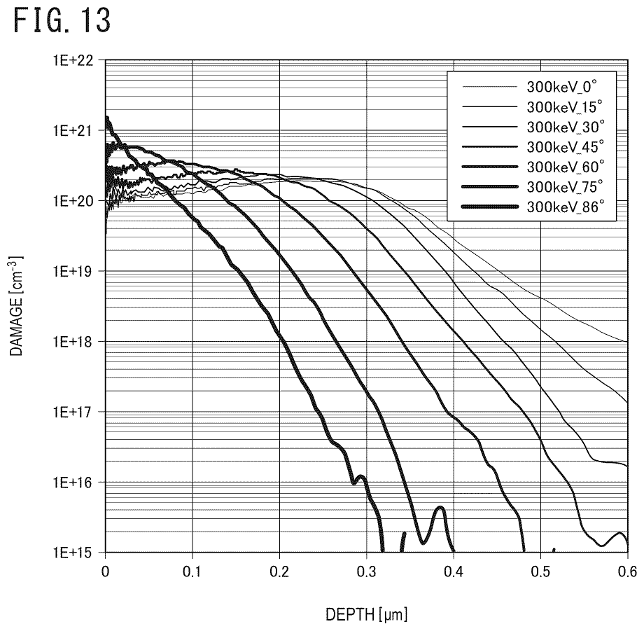

FIG. 13 is a graph showing results of Monte Carlo simulations of impurity profiles in a case of using Al as an ion species, setting an off-angle of the wafer to four degrees, setting a dose to 1×10¹³/cm⁻², fixing an implantation energy to 300 keV, and changing an implantation angle with respect to the normal line direction to the top surface of the wafer to 0°, 15°, 30°, 45°, 60°, 75°, and 86°. The axis of abscissas in FIG. 13 indicates a depth from the top surface of the wafer, and the axis of ordinates in FIG. 13 indicates an impurity concentration (damage).

The results revealed, as shown in FIG. 13, that the cases of setting the implantation angle to 0° and 15° both have the equivalent peak damage level. The damage level increases and 3C-SiC also increases as the implantation angle increases to 30° or larger. The implantation angle with respect to the normal line direction to the top surface of the wafer is thus preferably set to 30° or larger.

### Second Embodiment

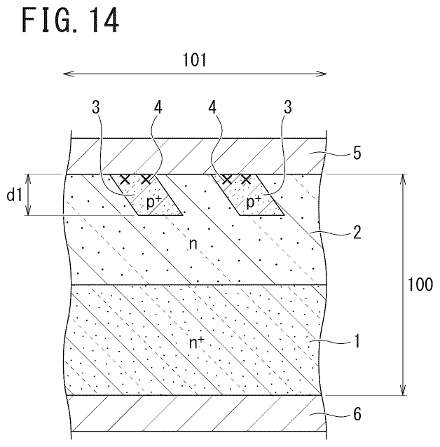

FIG. 14 is a cross-sectional view, as viewed from direction A-A in FIG. 1, illustrating a silicon carbide semiconductor device according to a second embodiment. As illustrated in FIG. 14, the silicon carbide semiconductor device according to the second embodiment differs from the silicon carbide semiconductor device according to the first embodiment in that the respective anode regions 3 have a substantially parallelogram in cross section taken along the direction orthogonal to the extending direction of the anode regions 3 in the planar pattern. Although not illustrated, the respective anode regions 3 have a substantially rectangular shape in cross section, as viewed from direction B-B in FIG. 1, taken along the extending direction of the anode regions 3 in the planar pattern. The other configurations of the silicon carbide semiconductor device according to the second embodiment are substantially the same as those of the silicon carbide semiconductor device according to the first embodiment, and overlapping explanations are not repeated below.

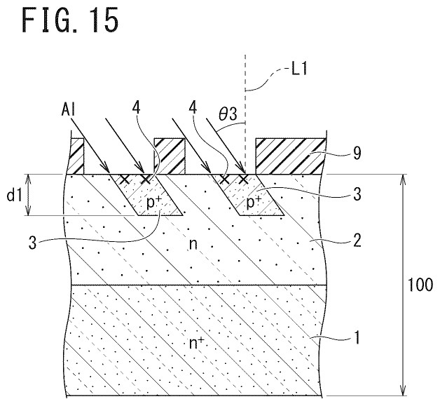

A method of manufacturing the silicon carbide semiconductor device according to the second embodiment delineates a photoresist film 9, and implants p-type impurity ions into the top surface of the semiconductor substrate 100 in an oblique direction inclined at an angle θ3 with respect to the normal line LI to the top surface of the semiconductor substrate 100 while using the delineated photoresist film 9 as a mask for ion implantation so as to form the anode regions 3, in the cross-sectional view taken along the direction orthogonal to the extending direction of the anode regions 3 in the planar pattern, as illustrated in FIG. 15. The other steps in the method of manufacturing the silicon carbide semiconductor device according to the second embodiment are substantially the same as those in the manufacturing the silicon carbide semiconductor device according to the first embodiment.

The silicon carbide semiconductor device according to the second embodiment and the method of manufacturing the same implant the p-type impurity ions into the top surface of the drift layer 2 in the oblique direction inclined only at the predetermined angle θ3 with respect to the normal line LI to the top surface of the semiconductor substrate 100, in the same manner as in the first embodiment. The present embodiment thus cause the damage 4 to the front-surface layer of the respective anode regions 3 to form 3C-SiC, so as to lead the anode regions 3 and the anode electrode 5 to be in ohmic contact with each other, while eliminating the provision of any silicide layers. The present embodiment can further increase the impurity concentration in the front-surface layer of the respective anode regions 3, so as to contribute to reducing the process load.

### Third Embodiment

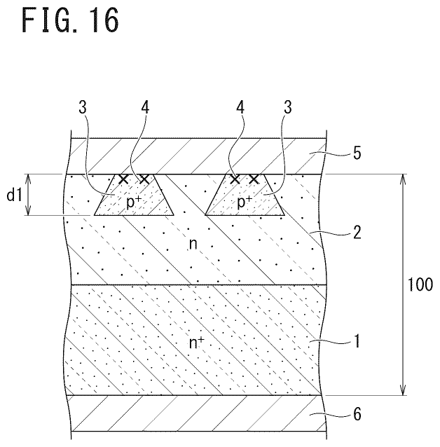

FIG. 16 is a cross-sectional view, as viewed from direction A-A in FIG. 1, illustrating a silicon carbide semiconductor device according to a third embodiment. As illustrated in FIG. 16, the silicon carbide semiconductor device according to the third embodiment differs from the silicon carbide semiconductor device according to the first embodiment in that the respective anode regions 3 have a substantially trapezoidal shape in cross section taken along the direction orthogonal to the extending direction of the anode regions 3 in the planar pattern. Although not illustrated, the respective anode regions 3 have a substantially rectangular shape in cross section, as viewed from direction B-B in FIG. 1, taken along the extending direction of the anode regions 3 in the planar pattern. The other configurations of the silicon carbide semiconductor device according to the third embodiment are substantially the same as those of the silicon carbide semiconductor device according to the first embodiment, and overlapping explanations are not repeated below.

A method of manufacturing the silicon carbide semiconductor device according to the third embodiment executes the step of the ion implantation for forming the anode regions 3 two times. The first ion implantation step delineates the photoresist film 9, and implants the p-type impurity ions into the top surface of the semiconductor substrate 100 in the oblique direction inclined at the angle θ3 with respect to the normal line L1 to the top surface of the semiconductor substrate 100 while using the delineated photoresist film 9 as a mask for ion implantation so as to form the anode regions 3, in the cross-sectional view takin along the direction orthogonal to the extending direction of the anode regions 3 in the planar pattern, as in the step in the method of manufacturing the silicon carbide semiconductor device according to the second embodiment illustrated in FIG. 15. The photoresist film 9 is then removed.

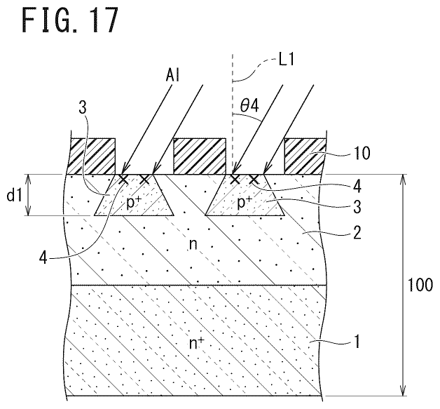

Next, the second ion implantation step delineates a photoresist film 10, and implants p-type impurity ions into the top surface of the semiconductor substrate 100 in an oblique direction inclined at an angle θ4 identical to the angle θ3 illustrated in FIG. 15 but opposite to the direction inclined at the angle θ3 with respect to the normal line L1 to the top surface of the semiconductor substrate 100 while using the delineated photoresist film 10 as a mask for ion implantation, in the cross-sectional view taken along the direction orthogonal to the extending direction of the anode regions 3 in the planar pattern, as illustrated in FIG. 17. The photoresist film 10 is then removed. Since the ion implantation for forming the anode regions 3 is repeated two times in this embodiment, the dose upon the ion implantation for forming the anode regions 3 is changed to be smaller for each step than the case of executing the single ion implantation. The other steps in the method of manufacturing the silicon carbide semiconductor device according to the third embodiment are substantially the same as those in the manufacturing the silicon carbide semiconductor device according to the first embodiment.

The silicon carbide semiconductor device according to the third embodiment and the method of manufacturing the same repeatedly execute the implantation of the p-type impurity ions into the top surface of the drift layer 2 in the oblique direction inclined at the predetermined angles θ3 and θ4 with respect to the normal line L1 to the top surface of the semiconductor substrate 100, in the same manner as in the first embodiment. The present embodiment thus cause the damage 4 to the front-surface layer of the respective anode regions 3 to form 3C-SiC, so as to lead the anode regions 3 and the anode electrode 5 to be in ohmic contact with each other, while eliminating the provision of any silicide layers. The present embodiment can further increase the impurity concentration in the front-surface layer of the respective anode regions 3, so as to contribute to reducing the process load.

Further, the silicon carbide semiconductor device according to the third embodiment and the method of manufacturing the same, which executes the step of the ion implantation for forming the anode regions 3 repeatedly two times, can provide the respective anode regions 3 formed into the substantially trapezoidal shape in cross section, so as to improve the symmetry of the shape.

### Fourth Embodiment

### Configuration of Silicon Carbide Semiconductor Device

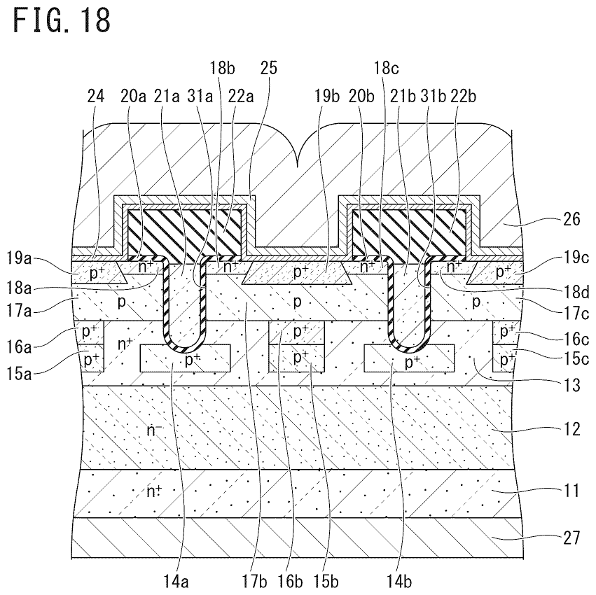

A silicon carbide semiconductor device according to a fourth embodiment is illustrated with a MOSFET below. The silicon carbide semiconductor device according to the fourth embodiment includes a drift layer 12 that is a semiconductor layer of the first conductivity-type (n-type), as illustrated in FIG. 18. The drift layer 12 is an epitaxial growth layer including SiC such as 4H-SiC.

A current spreading layer (CSL) 13 that is a semiconductor layer of n⁺-type having a higher impurity concentration than the drift layer 12 is provided on the top surface side of the drift layer 12. The current spreading layer 13 is an epitaxial growth layer including SiC such as 4H-SiC. The current spreading layer 13 can be a region obtained such that n-type impurity ions are implanted into the upper part of the drift layer 12. The current spreading layer 13 is not necessarily provided in this embodiment, and the drift layer 12 may be provided toward the region corresponding to the current spreading layer 13 if not provided.

Base regions 17a to 17c, which are each a semiconductor layer of the second conductivity-type (p-type), are provided on the top surface side of the current spreading layer 13. The respective base regions 17a to 17c are an epitaxial growth layer including SiC such as 4H-SiC. The respective base regions 17a to 17c can be a region obtained such that p-type impurity ions are implanted into the current spreading layer 13.

First main electrode regions (source regions) 18a to 18d, which are each a semiconductor layer of n⁺-type having a higher impurity concentration than the drift layer 12, are provided on the top surface sides of the base regions 17a to 17c. The source regions 18a to 18d are formed such that n-type impurity ions such as nitrogen (N), phosphorus (P), and arsenic (As) are implanted into the base regions 17a to 17c in an oblique direction inclined to the normal line to the top surfaces of the base regions 17a to 17c.

A depth of the respective source regions 18a to 18d is set in a range of about 0.1 micrometers or greater and 0.5 micrometers or less, for example, or may be in a range of about 0.1 micrometers or greater and 0.3 micrometers or less. The depth of the respective source regions 18a to 18d may be set to about 0.5 micrometers or greater. An impurity concentration in a region from the top surface of the respective source regions 18a to 18d to the depth of 0.3 micrometers is in a range of about 1×10¹⁸/cm³ or higher and 1×10²²/cm³ or lower, and preferably in a range of about 1×10¹⁸/cm³ or higher and 1×10²²/cm³ or lower so as to lead to lower resistance. The impurity concentration at the top surface of the respective source regions 18a to 18d may be set in a range of about 1×10²⁰/cm³ or higher and 1×10¹⁸/cm³ or lower. The impurity concentration in the region from the top surface of the respective source regions 18a to 18d to the depth of 0.3 micrometers may be uniform in the depth direction that is vertical to the top surfaces of the source regions 18a to 18d.

An impurity concentration in a region distant from the top surfaces of the source regions 18a to 18d by 0.5 micrometers or greater in the depth direction vertical to the top surfaces of the source regions 18a to 18d is lower than the impurity concentration in the region from the top surface of the respective source regions 18a to 18d to the depth of 0.3 micrometers. The impurity concentration in the region distant from the top surfaces of the source regions 18a to 18d by 0.5 micrometers or greater is about 1×10¹⁷/cm³ or lower, for example.

The respective source regions 18a to 18d mainly include 4H-SiC. The ion implantation for forming the source regions 18a to 18d causes damage to a part on the top surface side (the front-surface layer) including at least the top surfaces of the source regions 18a to 18d to destroy the crystal structure of 4H-SiC so as to form the amorphous structure. The annealing (activation annealing) executed later forms 3C-SiC when the amorphous structure is recrystallized. The front-surface layer of the respective source regions 18a to 18d thus includes 3C-SiC.

A proportion of 3C-SiC included in the front-surface layer of the respective source regions 18a to 18d is set in a range of about 10% or higher and 100% or lower, for example. The front-surface layer of the respective source regions 18a to 18d may include mixed crystals of 3C-SiC and 4H-SiC. The front-surface layer of the respective source regions 18a to 18d may include an amorphous structure, 4H-SiC, and the like, in addition to 3C-SiC. The inclusion of 3C-SiC in the front-surface layer of the respective source regions 18a to 18d can lead to an ohmic contact with a source electrode (24, 25, 26) provided on the top surface side of the source regions 18a to 18d at low resistance.

Base contact regions 19a to 19c, which are each a semiconductor layer of p⁺-type having a higher impurity concentration than the base regions 17a to 17c, are provided on the top surface sides of the base regions 17a to 17c so as to be in contact with the source regions 18a to 18d. The base contact regions 19a to 19c each have a substantially trapezoidal shape in cross section. The base contact regions 19a to 19c are formed such that p-type impurity ions such as aluminum (Al) and boron (B) are implanted into the base regions 17a to 17c in an oblique direction inclined to the normal line to the top surfaces of the base regions 17a to 17c.

A depth of the respective base contact regions 19a to 19c is set in a range of about 0.1 micrometers or greater and 0.5 micrometers or less, for example, or may be in a range of about 0.1 micrometers or greater and 0.3 micrometers or less. The depth of the respective base contact regions 19a to 19c may be about 0.5 micrometers or greater. An impurity concentration in a region from the top surface of the respective base contact regions 19a to 19c to the depth of 0.3 micrometers is set in a range of about 1×10¹⁸/cm³ or higher and 1×10²²/cm³ or lower, and preferably in a range of about 1×10¹⁸/cm³ or higher and 1×10²²/cm³ or lower so as to lead to lower resistance. The impurity concentration at the top surface of the respective base contact regions 19a to 19c may be in a range of about 1×10²⁰/cm³ or higher and 1×10²²/cm³ or lower. The impurity concentration in the region from the top surface of the respective base contact regions 19a to 19c to the depth of 0.3 micrometers may be uniform in the depth direction that is vertical to the top surfaces of the source regions 19a to 19c.

An impurity concentration in a region distant from the top surfaces of the base contact regions 19a to 19c by 0.5 micrometers or greater in the depth direction vertical to the top surfaces of the base contact regions 19a to 19c is lower than the impurity concentration in the region from the top surface of the respective base contact regions 19a to 19c to the depth of 0.3 micrometers. The impurity concentration in the region distant from the top surfaces of the base contact regions 19a to 19c by 0.5 micrometers or greater is about 1×10¹⁷/cm³ or lower, for example.

The respective base contact regions 19a to 19c mainly include 4H-SiC. The ion implantation for forming the base contact regions 19a to 19c causes damage to a part on the top surface side (the front-surface layer) including at least the top surfaces of the base contact regions 19a to 19c to destroy the crystal structure of 4H-SiC so as to form the amorphous structure. The annealing (activation annealing) executed later forms 3C-SiC when the amorphous structure is recrystallized. The front-surface layer of the respective base contact regions 19a to 19c thus includes 3C-SiC.

A proportion of 3C-SiC included in the front-surface layer of the respective base contact regions 19a to 19c is set in a range of about 10% or higher and 100% or lower, for example. The front-surface layer of the respective base contact regions 19a to 19c may include mixed crystals of 3C-SiC and 4H-SiC. The front-surface layer of the respective base contact regions 19a to 19c may include an amorphous structure, 4H-SiC, and the like, in addition to 3C-SiC. The inclusion of 3C-SiC in the front-surface layer of the respective base contact regions 19a to 19c can lead to an ohmic contact with the source electrode (24, 25, 26) provided on the top surface side of the base contact regions 19a to 19c at low resistance.

Trenches 31a and 31b are provided from the top surface side of the source regions 18a to 18d in the depth direction. The trenches 31a and 31b penetrate the source regions 18a to 18d and the base regions 17a to 17c to reach the current spreading layer 13. The trenches 31a and 31b may have a planar pattern extending in a stripe-shaped state in the backward direction and the frontward direction in the sheet of FIG. 18, or may have dotted planar pattern.

Gate insulating films 20a and 20b are provided along the bottom and side surfaces of the trenches 31a and 31b. Gate electrodes 21a and 21b are buried inside the trenches 31a and 31b with the gate insulating films 20a and 20b interposed.

The respective gate insulating films 20a and 20b as used herein can be a single-layer film of a silicon oxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The respective gate electrodes 21a and 21b can be made of a polysilicon layer (a doped polysilicon layer) heavily doped with either p-type or n-type impurities, or include refractory metal such as titanium (Ti), tungsten (W), and nickel (Ni), for example.

In order to protect the gate insulating films 20a and 20b at the bottom of the trenches 31a and 31b against high voltage upon reverse bias, gate bottom protection regions 14a and 14b of p⁺-type are provided so as to be in contact with the bottom of the respective trenches 31a and 31b.

Base bottom buried regions (15a, 16a), (15b, 16b), and (15c, 16c) of p⁺-type are arranged on the bottom surface side of the base regions 17a to 17c below the base contact regions 19a to 19c. The base bottom buried region (15a, 16a) includes a first buried region 15a, and a second buried region 16a provided on the top surface of the first buried region 15a. The base bottom buried region (15b, 16b) includes a first buried region 15b, and a second buried region 16b provided on the top surface of the first buried region 15b. The base bottom buried region (15c, 16c) includes a first buried region 15c, and a second buried region 16c provided on the top surface of the first buried region 15c.

The first main electrode (the source electrode) (24, 25, 26) is provided on the top surface side of the gate electrodes 21a and 21b with the interlayer insulating films 22a and 22b interposed. The respective interlayer insulating films 22a and 22b as used herein can be a silicon oxide film (a SiO₂ film) without containing impurities which is generally referred to as a non-doped silicate glass (NSG) film, a phosphosilicate glass film (a PSG film), or a borosilicate glass film (a BSG film), for example. Alternatively, the respective interlayer insulating films 22a and 22b may be a single-layer film of a borophosphosilicate glass film (a BPSG film) or a silicon nitride film (a Si₃N₄ film), or a composite film including the above films selectively combined and stacked together.

The source electrode (24, 25, 26) is in ohmic contact with the source regions 18a to 18d and the base contact regions 19a to 19c at low resistance. The source electrode (24, 25, 26) includes a first barrier metal layer 24, a second barrier metal layer 25, and a wire layer 26. The first barrier metal layer 24 is in contact with the respective base contact regions 19a to 19c and the respective source regions 18a to 18d. The second barrier metal layer 25 is provided to cover the first barrier metal layer 24. The wire layer 26 is provided to cover the second barrier metal layer 25. The first barrier metal layer 24 includes titanium nitride (TiN), the second barrier metal layer 25 includes titanium (Ti)/TiN/Ti, and the wire layer 26 includes aluminum (Al), for example. The part of the source electrode (24, 25, 26) in contact with the base contact regions 19a to 19c and the source regions 18a to 18d includes metal material such as aluminum (Al), an Al alloy, molybdenum (Mo), titanium (Ti), and titanium nitride (TiN).

A second main electrode region (a drain region) 11 of n⁺-type having a higher impurity concentration than the drift layer 12 is provided on the bottom surface side of the drift layer 12. The drain region 11 is implemented by a substrate (a SiC substrate) including SiC such as 4H-SiC.

A second main electrode (a drain electrode) 27 is provided on the bottom surface side of the drain region 11 so as to be in contact with each other. The drain electrode 27 as used herein can be a single layer including gold (Au), or a metallic film including Al, nickel (Ni), and Au sequentially stacked together, and may be further provided with a metallic plate including metal such as molybdenum (Mo) and tungsten (W) stacked on the lowermost layer.

The silicon carbide semiconductor device according to the fourth embodiment during the operation is provided with inversion layers (channels) formed in the base regions 17a to 17c toward the gate electrodes 21a and 21b so as to be in the ON-state when a positive voltage is applied to the drain electrode 27 and a positive voltage of a threshold or greater is applied to the gate electrodes 21a and 21b. In the ON-state, a current flows from the drain electrode 27 toward the source electrode (24, 25, 26) through the drain region 11, the drift layer 12, the respective inversion layers of the base regions 17a to 17c, and the source regions 18a to 18d. When the voltage applied to the respective gate electrodes 21a and 21b is smaller than the threshold, the silicon carbide semiconductor device is led to be in the OFF-state since no inversion layers are formed in the respective base regions 17a to 17c, while no current flows from the drain electrode 27 toward the source electrode (24, 25, and 26).

### Method of Manufacturing Silicon Carbide Semiconductor Device

An example of a method of manufacturing the silicon carbide semiconductor device according to the fourth embodiment is described below.

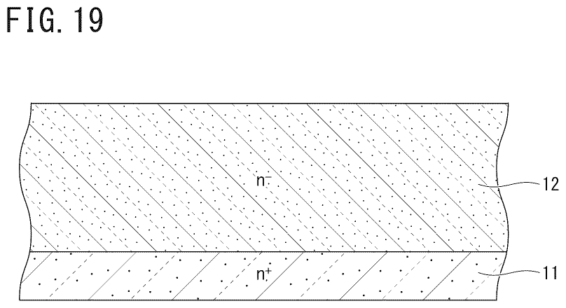

First, a semiconductor substrate (a SiC substrate) of n⁺-type including SiC such as 4H-SiC and doped with n-type impurities such as nitrogen (N) is prepared. The top surface of the SiC substrate can have an off-angle of about four degrees. Using the SiC substrate as the drain region 11, the n-type drift layer 12 including SiC such as 4H-SiC is epitaxially grown on the top surface of the drain region 11, as illustrated in FIG. 19.

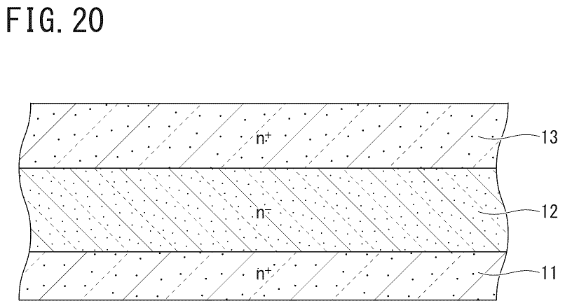

Next, n-type impurity ions such as nitrogen (N) are implanted into the entire top surface side of the drift layer 12, so as to form the n⁺-type current spreading layer 13 including SiC such as 4H-SiC, as illustrated in FIG. 20. The current spreading layer 13 may be epitaxially grown on the top surface of the drift layer 12 instead. The current spreading layer 13 is not necessarily provided in this case, and the following steps described below may be executed over the drift layer 12.

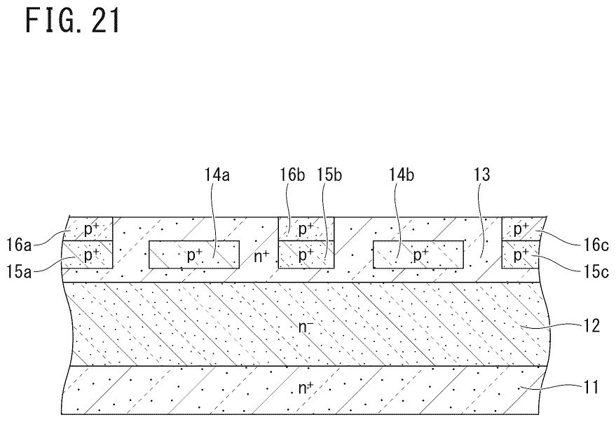

Next, the first buried regions 15a to 15c and the gate bottom protection regions 14a and 14b are formed inside the current spreading layer 13 by photolithography and ion implantation, as illustrated in FIG. 21. Further, the second buried regions 16a to 16c are formed on the top surface side of the first buried regions 15a to 15c at the upper part of the current spreading layer 13 by photolithography and ion implantation.

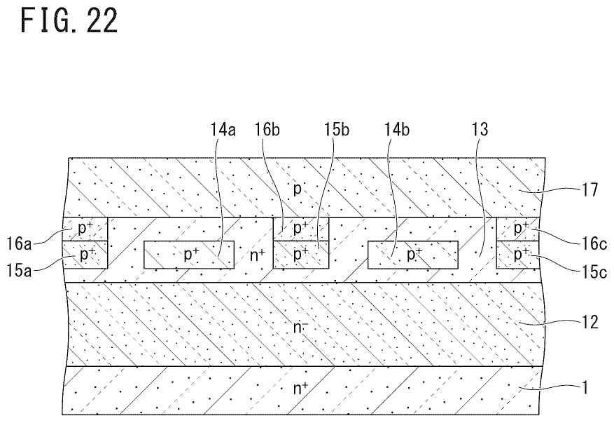

Next, as illustrated in FIG. 22, the p-type base region 17 including SiC such as 4H-SiC is epitaxially grown on the top surface of the current spreading layer 13.

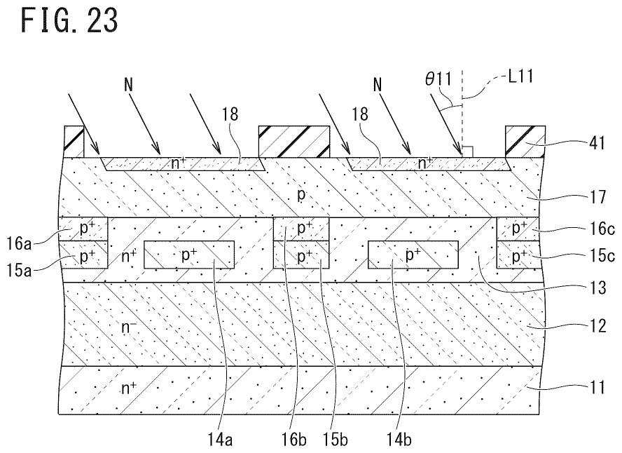

Next, a step of ion implantation for forming the n⁺-type source region 18 is executed separately two times. The first ion implantation step applies a photoresist film 41 onto the base region 17 (refer to FIG. 23), and delineates the photoresist film 41 by photolithography. Using the delineated photoresist film 41 as a mask for ion implantation, n-type impurity ions such as N are implanted into the base region 17 in an oblique direction inclined at a predetermined angle θ11 to the normal line L11 to the top surface of the base region 17, as illustrated in FIG. 23. This step forms the n⁺-type source region 18 having a substantially parallelogram in cross section. The photoresist film 41 is then removed. Instead of the photoresist film 41, an oxide film may be used as the mask.

The predetermined angle θ11 in the first ion implantation step is set in a range of about 30 degrees or greater and less than 90 degrees, for example, or may be set in a range of about 45 degrees or greater and less than 90 degrees or set in a range of about 60 degrees or greater and less than 90 degrees. An acceleration energy upon this ion implantation is set in a range of about 300 keV or higher and 700 keV or lower, or may be set in a range of 400 keV or higher and 700 keV or lower. Setting the acceleration energy upon the ion implantation to as high as 300 keV or higher can cause damage to the front-surface layer of the source region 18 to destroy the crystal structure of 4H-SiC, so as to form the amorphous structure.

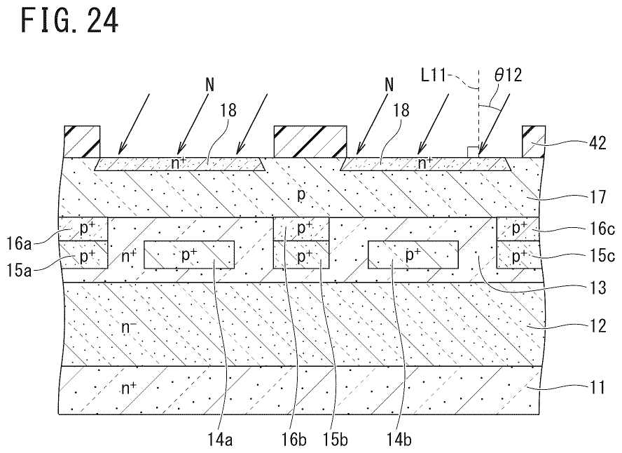

Next, the second ion implantation step applies a photoresist film 42 onto the base region 17 (refer to FIG. 24), and delineates the photoresist film 42 by photolithography. Using the delineated photoresist film 42 as a mask for ion implantation, n-type impurity ions such as N are implanted into the base region 17 in an oblique direction, opposite to that in the first ion implantation step, inclined at a predetermined angle θ12 identical to the predetermined angle θ11 to the normal line L11 to the top surface of the base region 17, as illustrated in FIG. 24. This step leads the regions implanted with the impurity ions in the first and second ion implantation steps to overlap with each other, so as to form the n⁺-type source region 18 having a substantially trapezoidal shape in cross section. The photoresist film 42 is then removed. Instead of the photoresist film 42, an oxide film may be used as the mask.

The predetermined angle θ12 in the second ion implantation step is set in a range of about 30 degrees or greater and less than 90 degrees, for example, or may be set in a range of about 45 degrees or greater and less than 90 degrees or set in a range of about 60 degrees or greater and less than 90 degrees. An acceleration energy upon this ion implantation is set in a range of about 300 keV or higher and 700 keV or lower, or may be set in a range of 400 keV or higher and 700 keV or lower. Setting the acceleration energy upon the ion implantation to as high as 300 keV or higher can cause damage to the front-surface layer of the source region 18 to destroy the crystal structure of 4H-SiC, so as to form the amorphous structure.

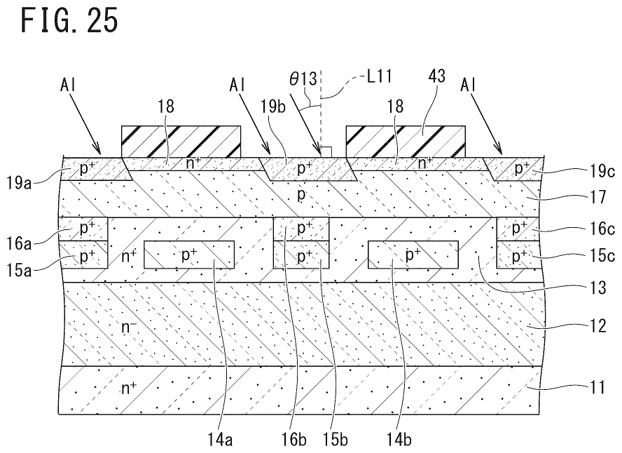

Next, a step of ion implantation for forming the p⁺-type base contact regions 19a to 19c is executed separately two times. The first ion implantation step applies a photoresist film 43 onto the base region 17 (refer to FIG. 25), and delineates the photoresist film 43 by photolithography. Using the delineated photoresist film 43 as a mask for ion implantation, p-type impurity ions such as Al are implanted into the base region 17 in an oblique direction inclined at a predetermined angle θ13 to the normal line L11 to the top surface of the base region 17. This step forms the p⁺-type base contact regions 19a to 19c having a substantially parallelogram in cross section on the top surface side of the base region 17. The photoresist film 43 is then removed. Instead of the photoresist film 43, an oxide film may be used as the mask.

The predetermined angle θ13 in the first ion implantation step is set in a range of about 30 degrees or greater and less than 90 degrees, for example, or may be set in a range of about 45 degrees or greater and less than 90 degrees or set in a range of about 60 degrees or greater and less than 90 degrees. An acceleration energy upon this ion implantation is set in a range of about 300 keV or higher and 700 keV or lower, or may be set in a range of 400 keV or higher and 700 keV or lower. Setting the acceleration energy upon the ion implantation to as high as 300 keV or higher can cause damage to the front-surface layer of the respective base contact regions 19a to 19c to destroy the crystal structure of 4H-SiC, so as to form the amorphous structure.

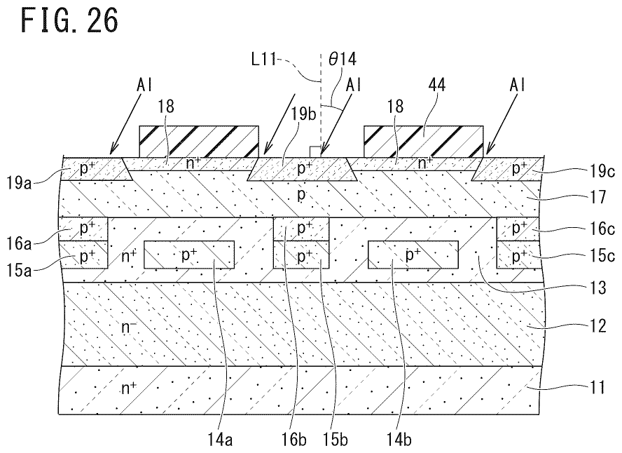

Next, the second ion implantation step applies a photoresist film 44 onto the base region 17 (refer to FIG. 26), and delineates the photoresist film 44 by photolithography. Using the delineated photoresist film 44 as a mask for ion implantation, p-type impurity ions such as Al are implanted into the base region 17 in an oblique direction, opposite to that in the first ion implantation step, inclined at a predetermined angle θ14 identical to the predetermined angle θ13 to the normal line L11 to the top surface of the base region 17, as illustrated in FIG. 26. This step leads the regions implanted with the impurity ions in the first and second ion implantation steps to overlap with each other, so as to form the p⁺-type base contact regions 19a to 19c having a substantially trapezoidal shape in cross section on the top surface side of the base region 17. The photoresist film 44 is then removed. Instead of the photoresist film 44, an oxide film may be used as the mask.

The predetermined angle θ14 in the second ion implantation step is set in a range of about 30 degrees or greater and less than 90 degrees, for example, or may be set in a range of about 45 degrees or greater and less than 90 degrees or set in a range of about 60 degrees or greater and less than 90 degrees. An acceleration energy upon this ion implantation is set in a range of about 300 keV or higher and 700 keV or lower, or may be set in a range of 400 keV or higher and 700 keV or lower. Setting the acceleration energy upon the ion implantation to as high as 300 keV or higher can cause damage to the front-surface layer of the respective base contact regions 19a to 19c to destroy the crystal structure of 4H-SiC, so as to form the amorphous structure.

Next, annealing (activation annealing) at a temperature in a range of 1600° C. or higher and 1900° C. or lower is executed so as to activate the n-type impurity ions and the p-type impurity ions implanted in the respective ion implantation steps. This step recrystallizes the amorphous structure on the respective front-surface layers of the source region 18 and the base contact regions 19a to 19c to form 3C-SiC.

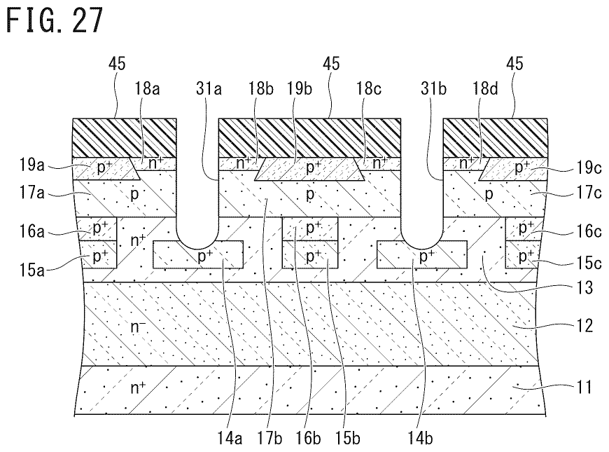

Next, a photoresist film 45 is applied onto the source region 18 and the base contact regions 19a to 19c (refer to FIG. 27), and is delineated by photolithography. Using the delineated photoresist film 45 as a mask for etching, the trenches 31a and 31b are selectively dug so as to penetrate the source regions 18a to 18d and the base regions 17a to 17c to reach the current spreading layer 13 by dry etching such as reactive ion etching (RIE), as illustrated in FIG. 27. The photoresist film 45 is then removed. Instead of the photoresist film 45, an oxide film may be used as the mask.

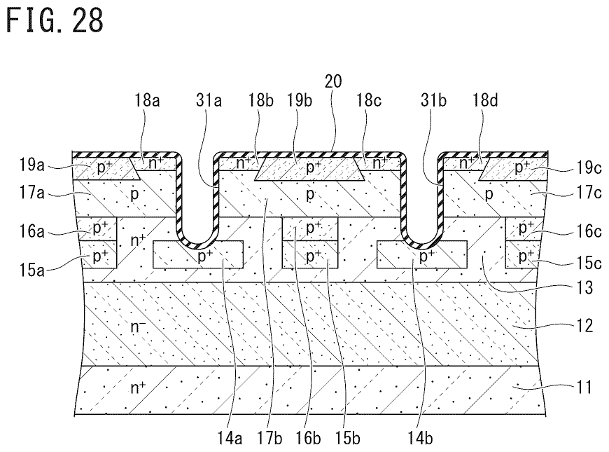

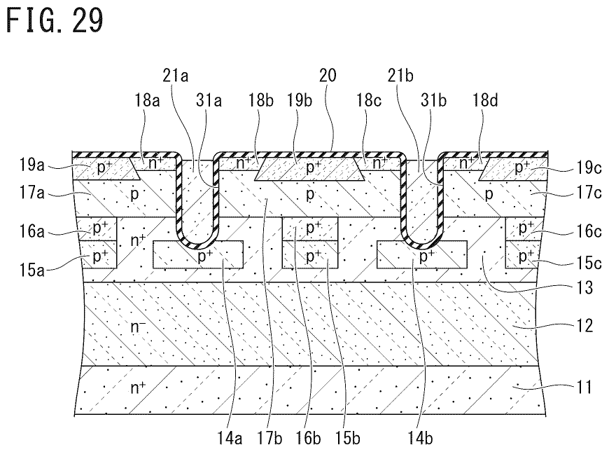

Next, as illustrated in FIG. 28, the gate insulating film 20 is formed along the bottom and side surfaces of the trenches 31a and 31b and the respective top surfaces of the source region 18 and the p⁺-type base contact regions 19a to 19c by a thermal oxidation method, a CVD method or the like. Next, a polysilicon layer (a doped polysilicon layer) heavily doped with impurities such as N is deposited on the gate insulating film 20 by a CVD method or the like. The polysilicon layer is then subjected to etch back to be buried inside the trenches 31a and 31b with the gate insulating film 20 interposed, so as to form the gate electrodes 21a and 21b, as illustrated in FIG. 29.

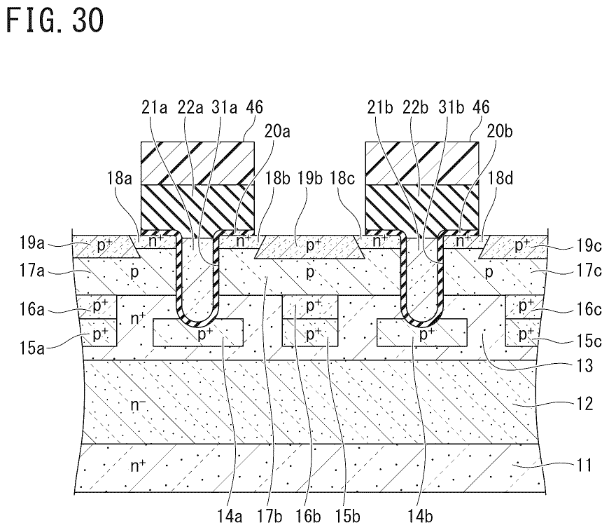

Next, an interlayer insulating film is deposited on the gate electrodes 21a and 21b and the gate insulating film 20 by a CVD method or the like. A photoresist film 46 is then applied onto the interlayer insulating film (refer to FIG. 30), and is delineated by photolithography. Using the photoresist film 46 as a mask for etching, the interlayer insulating films 22a and 22b and the gate insulating film 20 are partly and selectively removed by dry etching so as to open the contact holes, as illustrated in FIG. 30. The photoresist film 46 is then removed.

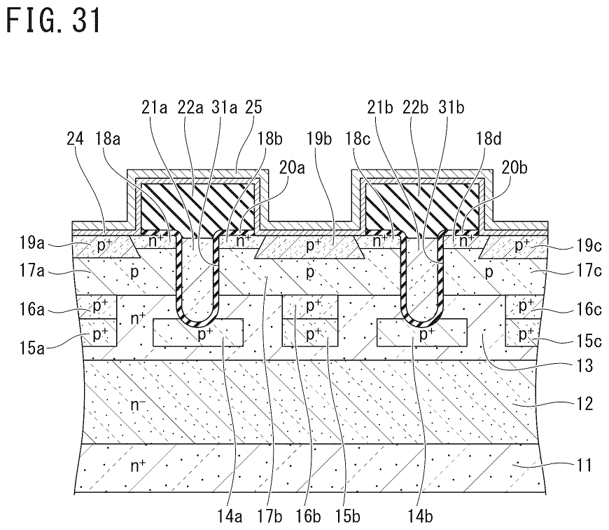

Next, the first barrier metal layer 24 and the second barrier metal layer 25 are formed by sputtering or evaporation method, as illustrated in FIG. 31. Next, the wire layer 26 illustrated in FIG. 18 is formed by sputtering or evaporation method. The first barrier metal layer 24, the second barrier metal layer 25, and the wire layer 26 thus obtained implement the source electrode (24, 25, 26). Thereafter, the drain electrode 27 illustrated in FIG. 18 is formed on the entire bottom surface of the drain region 11 by sputtering or evaporation method. The silicon carbide semiconductor device according to the fourth embodiment is thus completed.

The silicon carbide semiconductor device according to the fourth embodiment and the method of manufacturing the same may execute the ion implantation in the direction inclined at 30 degrees or greater and less than 90 degrees with respect to the normal line L11 to the top surface of the base region 17 with the acceleration energy of 300 keV or higher in either the ion implantation step for forming the base contact regions 19a to 19c or the ion implantation step for forming the source region 18. The present embodiment thus may have a configuration in which either the base contact regions 19a to 19c or the source regions 18a to 18d illustrated in FIG. 18 include 3C-SiC so as to be in ohmic contact with the source electrode (24, 25, 26) at low resistance.

Further, the ion implantation step for forming the n⁺-type source region 18 is not necessarily repeated separately two times, but only either the first step or the second step may be executed instead. When either the first step or the second step is executed, the n-type impurity ions such as N may be implanted into the entire top surface of the base region 17 in the oblique direction without use of the photoresist film 41 or 42. This case provides the source region 18 along the entire upper part of the base region 17. Further, since this case causes damage to the front-layer part of the source region 18 including the regions in which the p⁺-type base contact regions 19a to 19c are to be formed, the ion implantation step for forming the base contact regions 19a to 19c may execute the ion implantation in the direction corresponding to the normal line L11 to the top surface of the base region 17 at the acceleration energy of lower than 300 keV.

Further, the ion implantation step for forming the base contact regions 19a to 19c is not necessarily repeated separately two times, but only either the first step or the second step may be executed. This case leads the base contact regions 19a to 19c to have a substantially parallelogram in cross section.

The silicon carbide semiconductor device according to the fourth embodiment and the method of manufacturing the same include the ion implantation step for forming the source region 18 that implants the n-type impurity ions into the top surface of the base region 17 in the oblique direction inclined only at the respective predetermined angles θ11 and θ12 to the normal line L11 to the top surface of the base region 17, as illustrated in FIG. 23 and FIG. 24. The present embodiment can form the source region 18 in a shallow part regardless of the high acceleration energy, and cause damage to the front-surface layer of the source region 18 to form 3C-SiC, so as to lead the source region 18 and the source electrode (24, 25, 26) to be in ohmic contact with each other at low resistance. The present embodiment thus does not need to provide any silicide layers between the source region 18 and the source electrode (24, 25, 26), so as to eliminate a problem of unevenness caused on the front surfaces of the silicide layers to improve the reliability, and further eliminate the extra step of forming the silicide layers to reduce the costs. Further, the present embodiment can increase the impurity concentration on the front-surface layer of the source region 18 while causing damage to the top surface side of the source region 18, so as to reduce the process load accordingly.

Further, as illustrated in FIG. 25 and FIG. 26, the ion implantation step for forming the base contact regions 19a to 19c implants the p-type impurity ions into the top surface of the base region 17 in the oblique direction inclined only at the respective predetermined angles θ13 and θ14 to the normal line L11 to the top surface of the base region 17. The present embodiment can form the base contact regions 19a to 19c in a shallow part regardless of the high acceleration energy, and cause damage to the front-surface layer of the respective base contact regions 19a to 19c to form 3C-SiC, so as to lead the base contact regions 19a to 19c and the source electrode (24, 25, 26) to be in ohmic contact with each other at low resistance. The present embodiment thus does not need to provide any silicide layers between the base contact regions 19a to 19c and the source electrode (24, 25, 26), so as to eliminate a problem of unevenness caused on the front surfaces of the silicide layers to improve the reliability, and further eliminate the extra step of forming the silicide layers to reduce the costs. Further, the present embodiment can increase the impurity concentration on the front-surface layer of the respective base contact regions 19a to 19c while causing damage to the top surface side of the base contact regions 19a to 19c, so as to reduce the process load accordingly.

### Fifth Embodiment

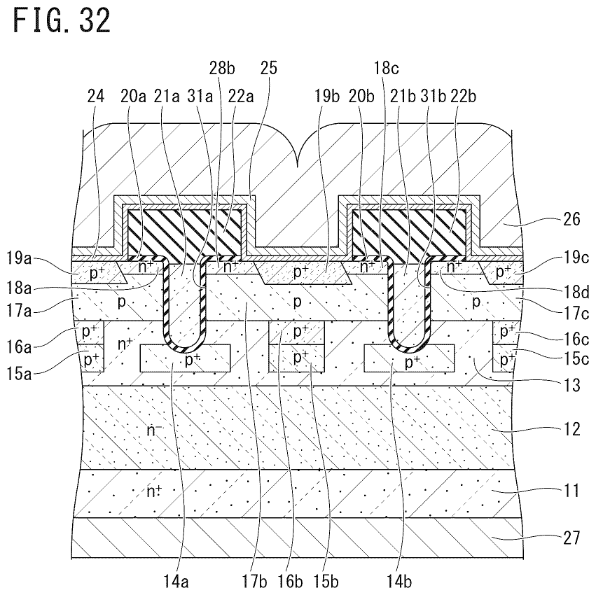

A silicon carbide semiconductor device according to a fifth embodiment differs from the silicon carbide semiconductor device according to the fourth embodiment illustrated in FIG. 18 in that the respective base contact regions 19a to 19c have a substantially parallelogram in cross section, as illustrated in FIG. 32. The other configurations of the silicon carbide semiconductor device according to the fifth embodiment are substantially the same as those of the silicon carbide semiconductor device according to the fourth embodiment, and overlapping explanations are not repeated below.

A method of manufacturing the silicon carbide semiconductor device according to the fifth embodiment differs from the method of manufacturing the silicon carbide semiconductor device according to the fourth embodiment in that the ion implantation for forming the base contact regions 19a to 19c is not divided into the two steps but only includes the first ion implantation step illustrated in FIG. 25 without the execution of the second ion implantation step illustrated in FIG. 26.

The silicon carbide semiconductor device according to the fifth embodiment and the method of manufacturing the same can achieve substantially the same effects as the silicon carbide semiconductor device according to the fourth embodiment and the method of manufacturing the same.

### Sixth Embodiment

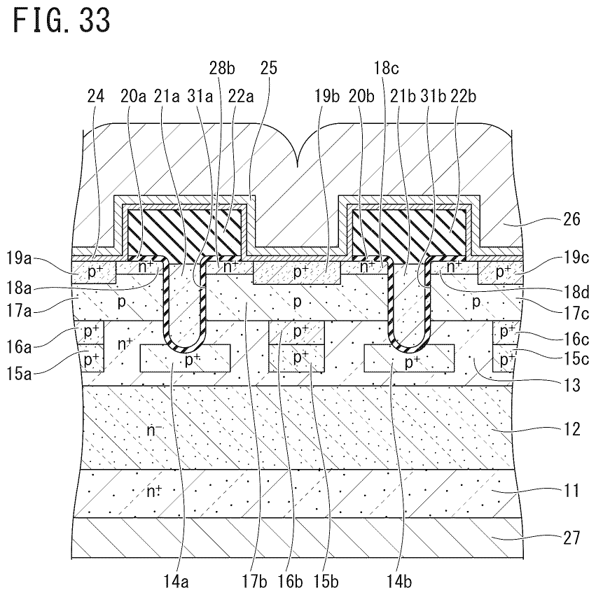

A silicon carbide semiconductor device according to a sixth embodiment differs from the silicon carbide semiconductor device according to the fourth embodiment illustrated in FIG. 18 in that the respective base contact regions 19a to 19c have a substantially rectangular shape in cross section, as illustrated in FIG. 33. The other configurations of the silicon carbide semiconductor device according to the sixth embodiment are substantially the same as those of the silicon carbide semiconductor device according to the fourth embodiment, and overlapping explanations are not repeated below.

A method of manufacturing the silicon carbide semiconductor device according to the sixth embodiment differs from the method of manufacturing the silicon carbide semiconductor device according to the fourth embodiment in that the two ion implantation steps for forming the base contact regions 19a to 19c implant the impurity ions in the oblique direction inclined to each of the frontward side and the backward side of the sheet of FIG. 33.

The silicon carbide semiconductor device according to the sixth embodiment and the method of manufacturing the same can achieve substantially the same effects as the silicon carbide semiconductor device according to the fourth embodiment and the method of manufacturing the same.

### Other Embodiments

As described above, the invention has been described according to the first to sixth embodiments, but it should not be understood that the description and drawings implementing a portion of this disclosure limit the invention. Various alternative embodiments of the present disclosure, examples, and operational techniques will be apparent to those skilled in the art from this disclosure.

For example, the fourth to sixth embodiments each have been illustrated with the case of using the MOSFET, but the present disclosure may also be applied to a case of using an IGBT. When using an IGBT, the present disclosure may have a configuration including an emitter region substituted for the respective n⁺-type source regions 18a to 18d and a p+-type collector region instead of the n⁺-type drain region 11 included in the MOSFET illustrated in FIG. 18. Further, the present disclosure may also be applied to a case of using a reverse conductive IGBT (RC-IGBT) or a reverse blocking IGBT (RB-IGBT), instead of a single IGBT. Further, the present disclosure has been illustrated above with the MOSFET having the trench-gate structure, but may also be applied to a MOSFET or an IGBT having a planer-gate structure.

In addition, the respective configurations disclosed in the first to sixth embodiments can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

1. A silicon carbide semiconductor device comprising:
a first semiconductor layer including 4H-SiC;
a second semiconductor layer provided on a top surface side of the first semiconductor layer and including 3C-SiC at least at a top surface; and
a main electrode provided on the top surface side of the second semiconductor layer,
wherein an impurity concentration from the top surface of the second semiconductor layer to a depth of 0.3 micrometers is 1×10¹⁸/cm³ or higher,
an impurity concentration at a depth of 0.5 micrometers or greater away from the top surface of the second semiconductor layer is 1×10¹⁷/cm³ or lower, and
the second semiconductor layer has an inclined side surface, and an angle between a normal line to the top surface of the second semiconductor layer and the inclined side surface is in a range of 30 degrees or greater and less than 90 degrees.

2. The silicon carbide semiconductor device of claim 1, wherein an impurity concentration at the top surface of the second semiconductor layer is 1×10²⁰/cm³ or higher.

3. The silicon carbide semiconductor device of claim 1, wherein the second semiconductor layer has a parallelogram in cross section.

4. The silicon carbide semiconductor device of claim 1, wherein the second semiconductor layer has a trapezoidal shape in cross section.

5. The silicon carbide semiconductor device of claim 1, wherein:
the first semiconductor layer is n-type and implements a Schottky junction with the main electrode; and
the second semiconductor layer is p-type and implements a p-n junction with the first semiconductor layer.

6. The silicon carbide semiconductor device of claim 1, wherein the second semiconductor layer implements a base contact region of p-type in a MOSFET.

7. The silicon carbide semiconductor device of claim 1, wherein the second semiconductor layer implements a main electrode region of n-type in a MOSFET.

8. The silicon carbide semiconductor device of claim 1, wherein a part of the main electrode in contact with the second semiconductor layer includes any of titanium, titanium nitride, aluminum, an aluminum alloy, and molybdenum.

9. A method of manufacturing a silicon carbide semiconductor device, comprising:
implanting impurity ions into a top surface of a first semiconductor layer including 4H-SiC in a direction inclined at an angle of 30 degrees or greater and less than 90 degrees to a normal line to the top surface of the first semiconductor layer so as to form a second semiconductor layer including 3C-SiC at least at a top surface on the top surface side of the first semiconductor layer; and
forming a main electrode on the top surface side of the second semiconductor layer.

10. The method of manufacturing the silicon carbide semiconductor device of claim 9, wherein an acceleration energy during the ion implantation is 300 keV or higher.

11. The method of manufacturing the silicon carbide semiconductor device of claim 9, wherein the ion implantation includes:
a first ion implantation of executing ion implantation in a direction inclined at a first angle of 30 degrees or greater and less than 90 degrees to the normal line to the top surface of the first semiconductor layer; and
a second ion implantation of executing ion implantation in a direction, opposite to that inclined at the first angle, inclined at a second angle identical to the first angle to the normal line to the top surface of the first semiconductor layer.

12. The method of manufacturing the silicon carbide semiconductor device of claim 9, wherein the angle during the ion implantation, when inclined in an off-angle direction of the first semiconductor layer, is set to less than an angle parallel to the off-angle direction.

13. The method of manufacturing the silicon carbide semiconductor device of claim 9, wherein the angle during the ion implantation is inclined in a direction different from an off-angle direction of the first semiconductor layer.

14. The method of manufacturing the silicon carbide semiconductor device of claim 9, wherein:
the second semiconductor layer has a planar shape extending in a striped state; and
the angle during the ion implantation is inclined in the extending direction.

15. The method of manufacturing the silicon carbide semiconductor device of claim 9, wherein:
the first semiconductor layer is n-type and implements a Schottky junction with the main electrode; and
the second semiconductor layer is p-type and implements a p-n junction with the first semiconductor layer.

16. The method of manufacturing the silicon carbide semiconductor device of claim 9, wherein the second semiconductor layer implements a base contact region of p-type in a MOSFET.

17. The method of manufacturing the silicon carbide semiconductor device of claim 9, wherein the second semiconductor layer implements a main electrode region of n-type in a MOSFET.
